(19) United States
(12) Patent Application Publication
(10) Pub. No.: US 2009/0226735 A1
(43) Pub. Date: Sep. 10, 2009

(54) VACUUM DEPOSITION METHOD

(75) Inventors: Nicolas Nadaud, Gentilly (FR); Eric Mattman, Paris (FR)

Correspondence Address: OBLON, SPIVAK, MCCLELLAND MAIER & NEUSTADT, P.C., 1940 DUKE STREET, ALEXANDRIA, VA, 22314, US

(73) Assignee: SAINT-GOBAIN GLASS FRANCE, Courbevoie (FR)

(21) Appl. No.: 11/578,938

(22) PCT Filed: Apr. 15, 2005
(86) PCT No.: PCT/FR2005/050250

§ 371 Date: Oct. 12, 2007

(30) Foreign Application Priority Data
Apr. 21, 2004 (FR) 0404204

(51) Int. Cl. B32B 9/00; C23C 14/46; C23C 14/35

(52) U.S. Cl. 428/446; 204/192.11

(57) ABSTRACT

Vacuum deposition process for depositing at least one thin film on a surface portion of a substrate, characterized in that:
at least one sputtering species that is chemically inactive or active with respect to a material to be sputtered is selected;
a collimated beam of ions comprising predominantly said sputtering species is generated using at least one linear ion source positioned within an installation of industrial size;
said beam is directed onto at least one target based on the material to be sputtered; and
at least one surface portion of said substrate is positioned so as to face said target in such a way that said material sputtered by the ion bombardment of the target or a material resulting from the reaction of said sputtered material with at least one of the sputtering species is deposited on said surface portion.

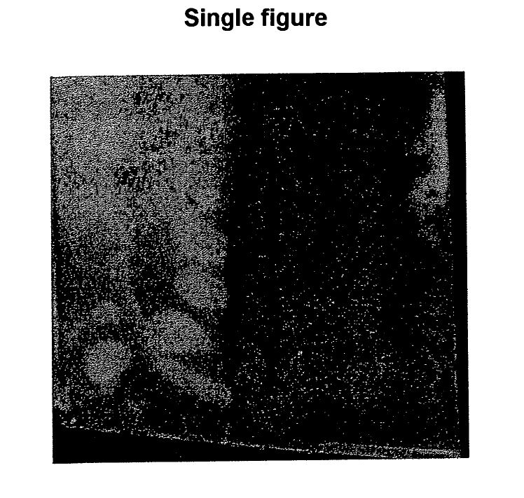

The present invention relates to a deposition process for depositing thin films on a substrate, especially a glass substrate. It relates more particularly to deposition processes intended to be integrated into vacuum installations for depositing films, these installations being of industrial size (for substrates whose dimension perpendicular to the direction of movement is greater than 1.5 m, or even 2 m). It also relates to substrates coated with a multilayer consisting of layers of various (solar control, low-emissivity, electromagnetic shielding, heating, hydrophilic, hydrophobic, photcatalytic) functionalities, which layers modify the level of reflection in the visible (mirror or antireflection layers in the visible or solar infrared range) incorporating an active (electrochromic, electroluminescent, photovoltaic, piezoelectric, scattering or absorbent) system.

Conventionally, deposition processes for depositing thin films on substrates, especially glass substrates, are employed within a megatron sputtering deposition line. These deposition techniques are satisfactory for large substrates but they do have, however, a number of drawbacks:
(i) the striking of the discharge plasma, called the “sputtering plasma”, requires a certain working pressure of at least 0.8 to 1 mtorr. Going below this pressure requires extremely intense magnetic fields, which are expensive, difficult to control in an industrial environment and result in a very low target material yield. It is also well known that a relatively high deposition pressure entails various disadvantages: (a) a higher defect (for example pinhole) density; (b) a lower energy of the sputtered particles (collision thermalization); (c) the inclusion of plasma gas, etc.;
(ii) the films deposited by a magnetron technique follow the Thornton model, that is to say their microstructure is predominantly columnar with a density and a mean diameter of the columns that vary according to the deposition pressure and to other parameters, such as the temperature of the substrate. This type of microstructure has a tendency to cause quite pronounced roughness of the deposited films to the detriment of some of their properties. The growing boundaries, predominantly perpendicular to the plane of the film, are also preferential penetration channels for chemical attack (for example by moisture in the air);
(iii) certain macroscopic properties of the thin films are intimately dependent on their microstructure, their state of crystallinity and their stoichiometry. These characteristics, for a given material, are dependent on the deposition conditions and in particular on the energy of the sputtered particles reaching the substrate. It is difficult by magnetron sputtering to control the energy of these particles (adatoms). One of the parameters easy to control is the deposition pressure, but there are no simple and reliable relationships, that can be generalized for all materials, between the working pressure and the energy of the neutral species expelled from the target. Most of the time the energy of the sputtered particles is not known and it depends on many parameters. A second parameter that has an influence on the morphology of the films is the sputtering angle. This is because, in conventional magnetron sputtering, the ionized gas atoms strike the target normally, i.e. perpendicular to the direction of the moving substrate, which means that a large part of the kinetic energy of a sputtered atom is transmitted to the substrate and does not contribute to the mobility of the adatom formed. The technique of off-axis sputtering (that is to say sputtering from the side) avoids this problem but it has a notoriously low deposition rate; and
(iv) magnetron sputtering can be used on cathodes with a length of greater than two meters (for deposition on substrates of similar specific size) only if the sinusoidal or pulsed bias voltage is applied, for example, at a frequency whose corresponding wavelength is large compared with the length of the cathode. Thus, uniform deposition is notoriously difficult using a 3 m cathode and radiofrequency sputtering (at around 13.56 MHz).

U.S. Pat. No. 6,214,183 discloses a deposition process that combines a linear ion source, the beam of which is suitable for sputtering the material of a target, and a magnetron sputtering device. This process is designed to allow deposition on substrates of small area (a few tens of cm² at the very most) and in a chamber operating in batch mode.

The present invention therefore aims to alleviate the drawbacks of the magnetron sputtering deposition processes.

For this purpose, the vacuum deposition process for depositing at least one thin film on a substrate is characterized in that:
at least one sputtering species that is chemically inactive or active with respect to a material to be sputtered is selected;
a collimated beam of ions comprising predominantly said sputtering species is generated using at least one linear ion source positioned within an installation of industrial size;
said beam is directed onto at least one target based on the material to be sputtered; and
at least one surface portion of said substrate is positioned so as to face said target in such a way that said material sputtered by the ion bombardment of the target or a material resulting from the reaction of said sputtered material with at least one of the sputtering species is deposited on said surface portion.

Thanks to these arrangements, it is possible to deposit at least one thin film of material on a surface portion of a substrate in a thin-film deposition installation, this installation being of industrial size and operating in a vacuum.

In preferred embodiments of the invention, one or more of the following arrangements may optionally be furthermore employed:
an operation for causing relative movement between the ion deposition source and the substrate is carried out;
the linear ion source generates a collimated ion beam of energy between 0.2 and 10 keV, preferably between 1 and 5 keV, especially close to 1.5 keV;
the installation is pressurized to a pressure lying within the range between 10⁻⁵ and 8×10⁻³ torr;
the ion beam and the target make an angle α of between 90° and 30°, preferably between 60° and 45°;
deposition takes place simultaneously or successively on two different surface portions of a substrate using at least said linear ion deposition source;
an additional species as a complement to said sputtering species is introduced, said additional species being chemically active with respect to said sputtered material;
the additional species is obtained from an injection of gas incorporating said additional species, for example in the vicinity of the substrate;
the target is biased so as to adjust the energy of the sputtering species;
the biased target is fixed to a cathode magnetron; and
an ion neutralizing device, possibly consisting of a nearby cathode magnetron, is positioned nearby.

According to another aspect of the invention, the latter also relates to a substrate, especially a glass substrate, at least one surface portion of which is coated with a thin-film multilayer formed from at least one first layer based on a metal oxide chosen especially from tin oxide or titanium oxide, silicon nitride/oxynitride, optionally doped with Al, and/or Zr, optionally a semiconductor or metal oxide layer, especially based on zinc oxide or titanium oxide, deposited on the first layer, a functional metal layer chosen especially from silver, platinum, gold and nickel-chromium, a metal layer chosen especially from nickel-chromium, titanium, niobium and zirconium, said metal layer being optionally nitrided or oxidized and deposited on or under (or both on and under) the silver layer, and at least one upper layer comprising a semiconductor or metal oxide chosen especially from tin oxide or titanium oxide, and silicon nitride, optionally doped, deposited on this metal layer, this upper layer possibly being a protective layer or overcoat, characterized in that at least one of the layers that is associated with the functional metal layer is deposited by the process described above.

According to yet another aspect of the invention, the latter also relates to a substrate, especially a glass substrate, at least one surface portion of which is coated with a thin-film multilayer comprising an alternation of n functional layers A having reflection properties in the infrared and/or in solar radiation, especially based on silver, and of (n+1) coatings B with n≧1, said coatings B comprising a layer or a superposition of layers made of dielectric material based especially on silicon nitride or on a mixture of silicon and aluminum, or silicon oxynitride, or zinc oxide, so that each functional layer A is placed between two coatings B, the multilayer also including layers C that absorb in the visible, especially based on titanium, nickel-chromium, or zirconium, these being optionally nitrided or oxidized, located above and/or below the functional layer, characterized in that at least one of the layers of the coating B or C is deposited by the process according to the invention.

According to a variant of the invention, the latter relates to a substrate, especially a glass substrate, at least one surface portion of which is coated with a thin-film multilayer comprising an alternation of n functional layers A having reflection properties in the infrared and/or in solar radiation, especially based on silver, and of (n+1) coatings B with n≧1, said coatings B comprising a layer or a superposition of layers made of dielectric material, so that each functional layer A is placed between two coatings B, characterized in that at least one of the layers of the coating A is deposited by the process according to the invention.

According to yet another feature of the invention, the latter relates to a substrate with a glazing function, especially a glass substrate, comprising, on at least one of its faces, a mirror or antireflection coating in the visible or solar infrared range, made from a thin-film multilayer (A), the layers being made of dielectrics of alternately high and low refractive index, characterized in that at least one of the layers is deposited by the abovementioned process.

In a preferred method of implementing the process according to the invention, this consists in inserting, into a line of industrial size (typically with a line width of about 3.5 m), for the deposition of thin films on a substrate, at least one linear ion deposition source. Within the context of the invention, the expression “industrial size” is understood to mean a production line whose size is suitable, on the one hand, for operating continuously and, on the other hand, for treating substrates, one of whose characteristic dimensions, for example the width perpendicular to the run direction of the substrate, is at least 1.5 m.

Within the context of the invention, the expression “ion deposition source” is understood to mean a complete system incorporating a linear ion source and a device that includes a target and a target holder.

This linear ion deposition source is positioned within a treatment chamber, the working pressure of which may be easily lowered to below 0.1 mtorr (about 133×10⁻⁴ Pa), and in practice from 1×10⁻⁵ to 5×10⁻³ torr.

This working pressure may be generally between 2 and 50 times lower than the low working pressure for a magnetron sputtering line, but the linear ion deposition device may also operate at the deposition pressure of a conventional magnetron process.

According to one advantageous feature of the invention, the fact of using not too high a working pressure range makes it possible to improve a number of properties within the layers that are deposited.

Thus, according to a first aspect of the invention, the layers deposited by the process according to the invention have a defect density that is very much lower than that which would be obtained if a conventional magnetron line (with its specific working pressure range) were to be used. The layers thus deposited make it possible for a multilayer stack to have an increased chemical durability as it is known that the resistance to chemical attack is improved when the number of defects in the terminal layers of the multilayers decreases (the defects are initiated from cavities/holes in the terminal layers). These defects in fact constitute points of preferential ingress of corrosive/damaging substances (water, acid, various corrosive agents) and are locally in the form of “holes”.

The presence of defects or holes in the terminal layers of a multilayer is particularly deleterious when said multilayer incorporates at least one silver layer. The presence of holes runs the risk of causing the appearance of pitting, for example in the presence of water or a humid atmosphere. It will therefore be understood that the chemical resistance of this type of multilayer is increased by reducing the density of holes.

Given below are embodiments of multilayer structures incorporating at least one layer made of a material sensitive to water vapour (typically a silver-based layer) and for which the process according to the invention is used to reduce the number of defects within the terminal layer.

Thus, according to a first embodiment, the substrate has a coating of the “enhanced thermal insulation” or low-E (low-emissivity) type. This coating consists of at least one sequence of at least five successive layers, namely a first layer based on a metal oxide chosen especially from tin oxide and titanium oxide (with a thickness of between 10 and 30 nm), a semiconductor or metal oxide layer, especially based on zinc oxide or titanium oxide, deposited (with a thickness of between 5 and 15 nm) on the first layer, a silver layer (with a thickness of between 5 and 15 nm), a metal layer chosen especially from nickel-chromium, titanium, niobium and zirconium, said metal layer being optionally nitrided or oxidized and deposited (with a thickness of less than 5 nm) on the silver layer, and at least one upper layer (with a thickness of between 5 and 45 nm) comprising a semiconductor or metal oxide chosen especially from tin oxide and titanium oxide, deposited on this metal layer, this upper layer (possibly consisting of a plurality of layers) possibly including a protective layer or overcoat.

Given below is an example of a substrate with a low-E multilayer:
substrate/SnO₂/ZnO/Ag/NiCr/SnO₂.

Using this example, it is proposed to compare the chemical durability properties obtained for this multilayer structure produced by a technique of the prior art (magnetron sputtering) with the same structure produced using the process according to the invention.

To do this, we give below the operating methodologies for the various mechanical and chemical durability tests employed in the following examples:

HCl Test:

10 minutes; 0.01 mol/l; 37° C.
measurement: change in reflection (ΔR) at 8 μm+observation of the defects.

NaOH Test:

10 minutes; 0.1 mol/l; room temperature.
measurement: reflection at 8 μm+observation of the defects.

HH (High Humidity) Test:

8 days; 90% relative humidity; 60° C.
measurement: observation of the defects.

Taber Test:

Abrasion by CS10F wheels.
measurement: percentage torn area.

Scratch Test:

The multilayer is scratched by a shaped steel tip (Bosch, R=0.75 mm) of calibrated radius of curvature. Measurement of the minimum force to be exerted on a tip in order to scratch the layer.

Thus, a silver-based multilayer according to the prior art, with a nickel-chromium sacrificial blocking metal layer and a tin oxide upper dielectric layer, was deposited on a glass substrate 4 mm in thickness.

A multilayer E1 of the type: substrate/SnO₂/ZnO/Ag/NiCr/SnO₂ (41 nm)^{MAG} was obtained. This multilayer E1 was produced by magnetron sputtering by making the substrate run through a chamber past metal targets based on the materials that had to be deposited, in an argon atmosphere for depositing a metal layer and in an argon/oxygen atmosphere in order to deposit an oxide.

This multilayer E1 was compared with a multilayer E2, whose terminal layer had the particular feature of having been divided into two: the first 20 nanometers were deposited by conventional magnetron sputtering and the other 21 nanometers (the outer part) were deposited by the process according to the invention:

Multilayer E2: substrate/SnO₂/ZnO/Ag/NiCr/SnO₂(20 nm)^{MAG}/SnO₂ (21 nm)^{IBS}.

The SnO₂^{MAG} was deposited by a reactive sputtering of a planar tin target, whereas the SnO₂^{IBS} was deposited by the process described above using a device installed in the same vacuum chamber. Consequently, the multilayer was not exposed to atmospheric pressure between the two terminal SnO₂ layers.

Within the present text, MAG is equivalent to “deposited by magnetron” and IBS is equivalent to “deposited by the process according to the invention, i.e. using a linear ion deposition source, or IBS (ion beam sputtering) process”.

Given below is a comparative table of the chemical durabilities:

| | HCl test | NaOH test |
|---|---|---|
| E1 (control) | ΔR = 1.9% | ΔR = 0.7% |
| | Pitting + intense | Color change |
| | haze | |
| E2 | ΔR = 0.3% | ΔR = −0.1% |
| | No pitting + | No color change |
| | slight haze | |

Given below is another example of a substrate coated with a low-E multilayer:
substrate/SnO₂/ZnO/Ag/NiCr/ZnO/Si₃N₄.

Using this example, the chemical durability properties were compared for this multilayer structure produced by a technique of the prior art (magnetron sputtering) with the same structure produced using the process according to the invention.

Thus, a silver-based multilayer according to the prior art, with a zinc oxide layer coated with a silicon nitride terminal layer, was deposited on a glass substrate 4 mm in thickness. A multilayer E3 of the type: substrate/SnO₂/ZnO/Ag/NiCr/ZnO/Si₃N₄ (20 nm)^{MAG} was obtained.

This multilayer E3 was produced by magnetron sputtering by making the substrate run through a chamber past metal targets based on the materials that had to be deposited.

This multilayer E3 was compared with a multilayer E4, whose terminal layer had the particular feature of having been divided into two: the 10 first nanometers were deposited by conventional magnetron sputtering and the other 10 nanometres (the outer part) were deposited by the process according to the invention.

Multilayer E4 substrate/SnO₂/ZnO/Ag/NiCr/ZnO/Si₃N₄ (10 nm)^{MAG}/Si₃N₄ (10 nm)^{IBS}.

Comparative table of the chemical durabilities:

| | HCl test | HH test |
|---|---|---|
| E3 (control) | ΔR = 0.9% | Haze |
| | Pitting | |
| E4 | ΔR = −0.2% | No haze |
| | No defects | |

According to a second aspect of the invention, the deposition process according to the invention makes it possible, in general, to improve the mechanical durability of the multilayer by controlling the level of compressive stress. More precisely, this improvement in mechanical durability is manifested by an increased resistance to “mechanical attack” of the scratching or abrasion type during the phases in which the multilayer-coated glazing is undergoing conversion or over its lifetime.

The known vacuum deposition processes of the prior art (magnetron processes) generally result in the formation of layers with very high compressive stresses.

To illustrate this characteristic, given below is an example of a substrate, includes a solar control coating, suitable for undergoing heat treatments (of the toughening type) and designed for specific applications in automobiles.

This coating consisted of a thin-film multilayer comprising an alternation of n functional layers A having reflection properties in the infrared and/or in solar radiation, especially based on silver (with a thickness of between 5 and 15 nm), and of (n+1) coatings B with n≧1, said coatings B comprising a layer or a superposition of layers made of dielectric material based especially on silicon nitride (with a thickness of between 5 and 80 nm), or on a mixture of silicon and aluminum, or silicon oxynitride, or zinc oxide (with a thickness of between 5 and 20 nm), so that each functional layer A is placed between two coatings B, the multilayer also including layers C that absorb in the visible, especially based on titanium, nickel-chromium or zirconium, these being optionally nitrided or oxidized, located above and/or below the functional layer.

Given below is an example of a substrate coated with this type of multilayer:

substrate/Si₃N₄/ZnO/Ti/Ag/ZnO/Si₃N₄/ZnO/Ti/Ag/ZnO/Si₃N₄.

Deposited in this multilayer, using a conventional vacuum deposition technique (magnetron sputtering) and the deposition process according to the invention, were silicon nitride layers that are known to possess notoriously high stress levels.

The multilayer E5 was the following:

substrate/Si₃N₄^{MAG}/ZnO/Ti/Ag/ZnO/Si₃N₄^{MAG}/ZnO/Ti/Ag/ZnO/Si₃N₄^{MAG}.

The multilayer E6 obtained using a linear ion deposition source, the collimated ion beam of which was optimized so as to deposit a layer based on silicon nitride with a reduced stress level, was the following:

### Si₃N₄^{MAG}/ZnO/Ti/Ag/ZnO/Si₃N₄^{IBS}/ZnO/Ti/Ag/ZnO/Si₃N₄^{IBS}.

The deposition conditions and the corresponding compressive stresses and roughness measurements for the Si₃N₄ layers produced by magnetron sputtering (MAG) and by the process according to the invention using IBS are given in the following table:

| | Si₃N₄ | |
|---|---|---|
| | by magnetron | Si₃N₄ |
| | sputtering | by IBS |
| | (Si:B target) | (Si:B target) |
| Thickness (nm) | 75 | 80 |
| Total pressure | 3 × 10⁻³ | 6 × 10⁻⁴ |
| (mbar) | | |
| Voltage (V) | 540 | 900 |
| Compressive | −1200 MPa | −80 MPa |
| stress (MPa) | | |
| Roughness (RMS in | 0.67 | 0.21 |
| nm, 0.5 × 0.5 μm²) | | |

The combination of dielectric layers with lower compressive stresses and less roughness results in improved scratch resistance:

| | Scratch test | Taber test |
|---|---|---|
| | (newtons) | 50 cycles; 250 grams |
| E5 (control) | 0.9 | 69% |
| E6 | 2.9 | 77% |

The layers obtained by IBS have a very low roughness compared with the other deposition techniques—the reader may refer to the following publication: Applied Surface Science, 205 (2003), 309-322.

According to a third aspect of the invention, the deposition process according to the invention makes it possible in general to improve the quality of the layers deposited, especially as this process reduces the roughness of the layers.

This is because it is of paramount importance to obtain an optimum (or even minimum) roughness when the layer in question is a functional layer or an underlayer that has to be coated with a functional layer.

Particularly when the functional layer is based on silver, it is known that the optimum emissivity, electrical conductivity and reflectivity in the infrared that are obtained depend on the roughness of the silver layer and that the roughness of the silver layer depends on the roughness of the layer preceding it in the multilayer.

Example E6a given below illustrates this property as regards the functional layer:
substrate/Si₃N₄/ZnO/Ti/Ag/ZnO/Si₃N₄.
   In this multilayer structure, a 10 nm silver layer was deposited by a conventional magnetron process and by the process according to the invention.

| | Magnetron | IBS |
|---|---|---|
| Surface resistance | 5.2 | 4.7 |
| (in ohms) | | |
| Roughness (RMS in nm; | 1.4 | 1.0 |
| 0.5 × 0.5 μm²) | | |
| Emissivity | 5.7 | 5.2 |

As may be seen for the dielectrics, the deposition process according to the invention reduces the roughness, therefore, as previously mentioned, reducing the surface resistance (lower resistivity and lower emissivity).

Example 6b illustrates the improvement in terms of roughness on a silica layer.

The roughness (determined by AFM on a 0.5×0.5 μm² quadrant) of the SiO₂ layer deposited by the process according to the invention is less than the roughness of the magnetron-deposited SiO₂ layer of the same thickness.

| | | | | | | RMS |
|---|---|---|---|---|---|---|
| | | | | | | roughness |
| | P | Ar | O₂ | Pressure | Thick. | in nm |
| Reference | (kW) | (sccm) | (sccm) | (mtorr) | (nm) | (AFM) |
| IBS | 1 | 15 | 15 | 1.23 | 126 | 0.4 |
| silica | | | | | | |
| Magnetron | 2 | 15 | 12 | 1.5 | 137 | 1.2 |
| silica | | | | | | |

Given below are various multilayer structures that illustrate this advantageous feature of the invention, some of the sublayers of which were deposited either by conventional techniques or by the process according to the invention.

Thus, the use of a ZnO sublayer deposited by the process according to the invention instead of a magnetron process makes it possible to reduce the roughness of the layer while maintaining its crystallinity necessary for heteroepitaxy of the silver. This effect is also detectable when the layer located beneath the oxide lying under the zinc oxide also has a reduced roughness by the use of a process employing a linear ion source focused onto the target (instead of the magnetron). This leads to a lower roughness of the silver layer, favorable to the electrical conduction properties.

The control multilayer E7 is the following: substrate/ZnO^{MAG} (32 nm)/Ag (10 nm)/NiCr (1 nm)/SnO₂ (25 nm).

This multilayer E7 is compared with the structures of multilayers E8 and E9, characterized by: multilayer E8: substrate/ZnO^{IBS} (32 nm)/Ag (10 nm)/NiCr (1 nm)/SnO₂ (25 nm).

multilayer E9: substrate/Si₃N₄^{IBS} (25 nm)/ZnO (10 nm)/Ag (10 nm)/NiCr (1 nm)/SnO₂ (25 nm).

| | Surface resistance | Normal emissivity |
|---|---|---|
| | (ohms) | (%) |
| E7 (control) | 4.8 | 5.1 |
| E8 | 4.1 | 4.5 |
| E9 | 4.4 | 4.8 |

According to a third aspect of the invention, the deposition process according to the invention makes it possible in general to improve the optical performance of the multilayers, and especially the antireflection multilayers or reflecting multilayers that comprise only dielectric layers.

Most of the antireflection coatings developed hitherto, using a vacuum deposition process, have been optimized so as to minimize the light reflection at normal incidence, without taking into account the optical appearance and esthetic character of the glazing when viewed obliquely, the mechanical durability of the multilayer, and the ability of the product to withstand heat treatments (of the toughening, annealing or bending type). It is thus known that, at normal incidence, it is possible to obtain very low light reflection values R_{L} with four-layer multilayers comprising a high-index layer/low-index layer/high-index layer/low-index layer alternation. The high-index layers are generally made of TiO₂ or Nb₂O₅, which have an effective high index, of about 2.45 and 2.35 respectively, and the low-index layers are usually made of SiO₂, with an index of about 1.45.

When it is desirable for the multilayer to maintain its optical properties, its mechanical properties (hardness, scratch resistance and abrasion resistance) and its chemical resistance, in a heat treatment (bending and/or toughening), it is known to use as high-index layer a layer based on Si₃N₄. However, its refractive index, which is approximately equal to 2.0 at 550 nm, limits the optical optimization possibilities.

The process according to the invention makes it possible to substantially improve the optical performance of the abovementioned multilayers. This is because it makes it possible to obtain thin films with a higher density than with the conventional techniques (magnetron sputtering), this increase in density resulting in an increase in the refractive index.

According to another example of a method of implementing the process, this makes it possible to produce, on a substrate, especially a glass substrate, comprising on at least one of its faces, a thin-film multilayer that includes at least one terminal layer whose purpose is to modify the surface energy with respect to water. This terminal layer may thus have hydrophobic properties (static contact angle greater than or equal to 80°), or else, on the contrary, it may have hydrophilic properties (static contact angle less than 20°).

Given below is a table that compares the refractive indices of the high-index materials (n measured by ellipsometry at 550 nm):

| | Magnetron (100 nm) | IBS (100 nm) |
|---|---|---|
| TiO₂ | 2.35 to 2.40 | 2.49 |
| Nb₂O₅ | 2.30 | 2.35 |
| Zro₂ | 2.13 | 2.26 |

This characteristic is illustrated for example by the optical performance (resulting from optical simulations) of multilayers of identical symmetrical structure E10 to E14: namely SiO₂^{MAG}/TiO₂/SiO₂^{MAG}/M/substrate/M/SiO₂^{MAG}/TiO₂/SiO₂^{MAG}.

| | | | 0° | | | 60° | | |
|---|---|---|---|---|---|---|---|---|
| | TiO₂ | M | R_{L} | a* | b* | R_{L} | a* | b* |
| E10 | MAG | TiO₂^{MAG} | 0.73% | −3.7 | −3.4 | 8.6% | −2.9 | −3.0 |
| E11 | IBS | TiO₂^{IBS} | 0.71% | −3.8 | −4.4 | 9.8% | −3.5 | −4.5 |
| E12 | MAG | Si₃N₄^{MAG} | 0.72% | −3.6 | −4.2 | 8.6% | −1.5 | −4.1 |
| E13 | IBS | Si₃N₄^{MAG} | 0.78% | −2.9 | −7.6 | 7.3% | +3.28 | −7.6 |
| E14 | IBS | TiO₂^{MAG} | 0.70% | −4.0 | −4.4 | 9.7% | −3.9 | −3.8 |

| | | | | | | |
|---|---|---|---|---|---|---|
| Intended optical | 0.6% | −5 | −5 | — | −5 | −5 |
| target | | | | | | |

It is apparent that combining the materials susceptible to conventional magnetron sputtering and to IBS deposition makes it possible to increase the optical performance of the antireflection coatings.

Irrespective of the example, at least one linear ion deposition source is used whose operating principle is as follows:

The linear ion source comprises, very schematically, an anode, a cathode, a magnetic device and a gas injection source. Examples of this type of source are described for example in RU 2 030 807, U.S. Pat. No. 6,002,208 or WO 02/093987. The anode is raised to a positive potential by a DC power supply, the potential difference between the anode and the cathode causing a gas injected nearby to be ionized. In this case, the gas injected may be a gas mixture based on oxygen, argon, nitrogen or helium, a noble gas, such as for example also neon, or a mixture of these gases.

The gas plasma is then subjected to a magnetic field (generated by permanent or nonpermanent magnets), thereby accelerating and focusing the ion beam. The ions are therefore collimated and accelerated toward the outside of the source in the direction of at least one target, which is possibly biased, the material of which it is desired to sputter, and their intensity depends in particular on the geometry of the source, on the gas flow rate, on the nature of the gases, and on the voltage applied to the anode. In particular, the operating parameters of the ion deposition source are adapted so that the energy and the acceleration transmitted to the collimated ions are sufficient to sputter, owing to their mass and their effective sputtering cross section, material aggregates of the material forming the target.

The respective orientation of the ion source (or ion sources) and that of the target is such that the ion beam (or ion beams) ejected from the source will sputter the target at one or more mean angles determined in advance (these being between 90° and 30°, preferably between 60° and 45°). The sputtered atom vapor must be able to reach a moving substrate whose width is at least 1 meter (1 m being a critical size above which an installation may be termed an industrial installation).

As a variant, the target may be incorporated into a magnetron sputtering device.

Close to the substrate, it is possible to inject, optionally, by means of a gas injection device, a second species in the form of a gas or a plasma, which is chemically active with respect to the sputtered or bombarded material coming from the target.

It is possible to integrate several sources into a production line, it being possible for the sources to operate on the same face of a substrate or on each of the faces of a substrate (an up-and-down sputtering line for example), simultaneously or consecutively.

Moreover, it is possible to equip the linear ion deposition source with an ion neutralizing device (electron source) so as to prevent the target from charging up and preventing arcs appearing inside the deposition chamber. This device may consist of a cathode magnetron operating nearby.

The substrates at the surface of which it is intended to deposit the abovementioned thin films are preferably transparent, flat or curved, and made of glass or a plastic (PMMA, PC, etc.).

Even more generally, the process according to the invention makes it possible to produce, in an industrial-sized chamber, a substrate, especially a glass substrate, comprising, on at least one of its faces, a thin-film multilayer that includes at least one layer deposited by said process and the roughness/stress/defect density/crystallinity state/optical dispersion law of which has(have) been modified relative to a multilayer comprising only layers deposited by magnetron sputtering.

In an industrial-sized chamber, it is possible to couple the linear ion source directed onto a target with another linear ion source directed toward the layer covering the substrate, said layer resulting from sputtering said target.

Likewise, it is possible to couple an ion source directed onto the target in a chamber or in the immediate vicinity of a chamber incorporating conventional cathodes, these cathodes possibly being plane or rotary, with one or two tubes.

The target used within the ion deposition device may be a plurality of plates or tubes, which are stationary or else capable of moving during the process.

These substrates thus coated form glazing units intended for applications in the automobile industry, especially an automobile sunroof, a side window, a windshield, a rear window, a rearview mirror, a single-glazing or double-glazing unit for buildings, especially an interior or exterior window for buildings, a display cabinet, a store counter, which may be curved, a glazing unit for protecting an object of the painting type, a computer antiglare screen, glass furniture, a breast wall, or an antifouling system.

1-20. (canceled)

21. A vacuum deposition process for depositing at least one thin film on a substrate characterized in that:
at least one gaseous sputtering species that is chemically inactive or active with respect to a material to be sputtered is selected;
a collimated beam of ions comprising predominantly said sputtering species is generated using at least one linear ion source positioned within an installation of industrial size;
said beam is directed onto at least one target based on the material to be sputtered; and
at least one surface portion of said substrate is positioned so as to face said target in such a way that said material sputtered by the ion bombardment of the target or a material resulting from the reaction of said sputtered material with at least one of the sputtering species is deposited on said surface portion.

22. The process as claimed in claim 21, characterized in that an operation for causing relative movement between the ion deposition source and the substrate is carried out.

23. The process as claimed in claim 21, characterized in that said linear ion source generates a collimated ion beam of energy between 0.2 and 10 keV.

24. The process as claimed in claim 21, characterized in that the installation is pressurized to a pressure within the range between 10⁻⁵ and 8×10⁻³ torr.

25. The process as claimed in claim 21, characterized in that the ion beam and the target make an angle α of between 90° and 30°.

26. The process as claimed in claim 21, characterized in that deposition takes place simultaneously or successively on two different surface portions of a substrate using at least said linear ion deposition source.

27. The process as claimed in claim 21, characterized in that an additional species as a complement to said sputtering species is introduced, said additional species being chemically active with respect to said sputtered material.

28. The process as claimed in claim 27, characterized in that the additional species is obtained from an injection of gas incorporating said additional species.

29. The process as claimed in claim 21, characterized in that the target is biased so as to adjust the energy of the sputtering species.

30. The process as claimed in claim 21, characterized in that an ion neutralizing device is positioned near the ion deposition source, said device consisting of a nearby cathode magnetron.

31. The process as claimed in claim 30, characterized in that a biased target is fixed to said cathode magnetron.

32. The process as claimed in claim 21, characterized in that at least one linear ion source, the ion beam of which is directed onto a target, and at least one cathode magnetron are coupled in one and the same compartment of a deposition chamber.

33. The process as claimed in claim 21, characterized in that a linear ion source, the ion beam of which is directed onto a target, and another ion source, the beam of which is directed onto the film resulting from the sputtering of the target, are coupled in one and the same compartment of a deposition chamber.

34. A substrate at least one surface portion of which is coated with a thin-film multilayer comprising an alternation of n functional layers having reflection properties in the infrared and/or in solar radiation and of (n+1) coatings B with n≧1, said coatings B comprising a layer or a superposition of layers made of dielectric material based on silicon nitride or on a mixture of silicon and aluminum, or silicon oxynitride, or zinc oxide, or tin oxide, or titanium oxide, so that each functional layer A is placed between two coatings B, characterized in that at least one of the layers of the coating B is deposited by the process as claimed in claim 21.

35. A substrate at least one surface portion of which is coated with a thin-film multilayer comprising an alternation of n functional layers having reflection properties in the infrared and/or in solar radiation and of (n+1) coatings B with n≧1, said coatings B comprising a layer or a superposition of layers made of dielectric material, so that each functional layer is placed between two coatings B, characterized in that at least one of the layers of A is deposited by the process as claimed in claim 21.

36. A substrate at least one surface portion of which is coated with a thin-film multilayer comprising an alternation of n functional layers having reflection properties in the infrared and/or in solar radiation and of (n+1) coatings B with n≧1, said coatings B comprising a layer or a superposition of layers made of dielectric material based on silicon nitride or on a mixture of silicon and aluminum, or silicon oxynitride, or zinc oxide, or tin oxide, or titanium oxide, so that each functional layer A is placed between two coatings B, characterized in that the multilayer also includes at least one metal layer C located above and/or below said functional layer, said layer C being deposited by the process as claimed in claim 21.

37. A substrate comprising, on at least one of its faces, a mirror or antireflection coating in the visible or solar infrared range, made from a thin-film multilayer (A), the layers being made of dielectrics of alternately high and low refractive index, characterized in that at least one of said layers is deposited by the process as claimed in claim 21.

38. A substrate comprising, on at least one of its faces, a thin-film multilayer that includes at least one layer deposited by the process as claimed in claim 21 and the roughness/stress/defect density/crystallinity state/optical dispersion law of which has(have) been modified relative to a multilayer comprising only layers deposited by magnetron sputtering.

39. A substrate comprising, on at least one of its faces, a thin-film multilayer that includes at least one terminal layer whose purpose is to modify the surface energy or to modify the friction coefficient, characterized in that said terminal layer is deposited by the process as claimed in claim 21.

40. The substrate as claimed in claim 34, characterized in that it is an automobile sunroof, side window, windshield, rear window, or rearview mirror, single-glazing or double-glazing unit for buildings, an interior or exterior window for buildings, a display cabinet, a store counter, which may be curved, a glazing unit for protecting an object of the painting type, an antiglare screen, glass furniture, optionally incorporating a photovoltaic system, a display screen, a breast wall, or an antifouling system.
